(19) United States
(12) Patent Application Publication
(10) Pub. No.: US 2026/0120784 A1
(43) Pub. Date: Apr. 30, 2026

(54) Memory Device with Low Wire Resistance and Method of Manufacturing the Same

(71) Applicant: Taiwan Semiconductor Manufacturing Company, Ltd., Hsinchu (TW)

(72) Inventors: Yorinobu Fujino, Hsinchu (TW); Yumito Aoyagi, Hsinchu (TW); Sheng-Po Huang, Hsinchu (TW); Ku-Feng Lin, Hsinchu (TW); Yi-Chun Shih, Hsinchu (TW)

(21) Appl. No.: 19/053,490

(22) Filed: Feb. 14, 2025

Related U.S. Application Data
(60) Provisional application No. 63/712,715, filed on Oct. 28, 2024.

(51) Int. Cl. G11C 17/16; G11C 17/18; H10B 20/25

(52) U.S. Cl. CPC G11C 17/16; G11C 17/18; H10B 20/25

(57) ABSTRACT

A memory device includes a plurality of memory cells, a word line, a plurality of bit lines, and a plurality of source lines. Each memory cell includes an one-time programmable (OTP) element and a plurality of select transistors. The word line is connected to gate terminals of the select transistors of a memory cell. The bit lines are connected in parallel between a first node and a first OTP element terminal of the OTP element of the memory cell. The source lines are connected in parallel and connects second source/drain terminals of the select transistors of the memory cell to a second node. A method for manufacturing the memory device is also disclosed.

### CROSS-REFERENCE TO RELATED APPLICATION

The present application claims priority to U.S. Application No. 63/712,715, filed Oct. 28, 2024, the contents of which are incorporated by reference herein in its entirety.

### BACKGROUND

Memory devices are responsible for storing and retrieving data. They come in various forms and can either be programmable or non-programmable. Programmable memory devices, such as RAM (random access memory) devices, allow data to be written and rewritten multiple times, making them suitable for applications requiring frequent updates. Non-programmable memory devices, on the other hand, such as OTP (one-time programmable) memory devices, can only be written once. Such devices maybe used in various applications where data needs to stay secure and cannot be tampered with. Regardless of their programmability, memory devices facilitate the reading of data stored therein, enabling electronic systems to access and utilize the information as needed.

### BRIEF DESCRIPTION OF THE DRAWINGS

Aspects of the present disclosure are best understood from the following detailed description when read with the accompanying figures:

FIG. 1 is a schematic circuit diagram illustrating an exemplary memory device in accordance with various embodiments of the present disclosure;

FIG. 2A is a schematic circuit diagram illustrating an exemplary memory cell in accordance with various embodiments of the present disclosure;

FIG. 2B is a schematic timing diagram illustrating an exemplary relationship among a word line signal, a bit line signal, and a source line signal in accordance with various embodiments of the present disclosure;

FIG. 3 is a schematic circuit diagram illustrating another exemplary memory cell in accordance with various embodiments of the present disclosure;

FIG. 4 is a schematic layout diagram illustrating exemplary conductive lines of a memory cell in accordance with various embodiments of the present disclosure;

FIG. 5 is a schematic layout diagram illustrating another exemplary conductive lines in accordance with various embodiments of the present disclosure; ;

FIG. 6A is a schematic circuit diagram illustrating another exemplary memory device in accordance with various embodiments of the present disclosure;

FIG. 6B is a schematic timing diagram illustrating an exemplary relationship among a word line signal, a bit line signal, and a source line signal in accordance with various embodiments of the present disclosure;

FIG. 7 is a schematic layout diagram illustrating another exemplary conductive lines in accordance with various embodiments of the present disclosure;

FIG. 8 is a schematic layout diagram illustrating another exemplary conductive lines in accordance with various embodiments of the present disclosure;

FIG. 9 is a schematic layout diagram illustrating another exemplary conductive lines in accordance with various embodiments of the present disclosure;

FIG. 10 is a schematic layout diagram illustrating another exemplary conductive lines in accordance with various embodiments of the present disclosure;

FIG. 11 is a schematic layout diagram illustrating another exemplary conductive lines in accordance with various embodiments of the present disclosure;

FIG. 12 is a schematic layout diagram illustrating another exemplary conductive lines of a memory cell in accordance with various embodiments of the present disclosure;

FIG. 13 is a schematic circuit diagram illustrating another exemplary memory device in accordance with various embodiments of the present disclosure;

FIG. 14 is a schematic circuit diagram illustrating another exemplary memory device in accordance with various embodiments of the present disclosure;

FIG. 15 is a schematic circuit diagram illustrating another exemplary memory device in accordance with various embodiments of the present disclosure;

FIG. 16 is a schematic circuit diagram illustrating another exemplary memory device in accordance with various embodiments of the present disclosure;

FIG. 17 is a schematic circuit diagram illustrating another exemplary memory device in accordance with various embodiments of the present disclosure;

FIG. 18 is a schematic circuit diagram illustrating another exemplary memory device in accordance with various embodiments of the present disclosure;

FIG. 19 is a schematic circuit diagram illustrating another exemplary memory device in accordance with various embodiments of the present disclosure;

FIG. 20 is a flowchart of an exemplary method of manufacturing a memory device in accordance with various embodiments of the present disclosure; and

FIG. 21 is a schematic sectional diagram illustrating another exemplary memory device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

A memory device includes a plurality of memory cells, e.g., arranged in an array of rows and columns, and facilitates data storage and retrieval. Memory devices can be either programmable or non-programmable. Programmable memory devices, such as RAM (random access memory) devices, allow data to be written and rewritten multiple times, making them suitable for applications requiring frequent updates, such as in RAM (random access memory) devices. Non-programmable memory devices, such as OTP (one-time programmable) memory devices, can be written to only once, ensuring that the data remains permanent and secure from alteration. They are useful in various applications where data needs to stay secure and cannot be tampered with.

However, OTP memory devices may sometimes fail to program. For example, during a programming operation, a programming voltage is applied across a memory cell of the OTP memory device via a bit line. The bit line may have a higher-than-expected wire resistance (e.g., via a fabrication anomaly) that limits the current flow needed to program the memory cell, resulting in a programming failure.

In certain examples described herein, systems and methods comprise a memory device that includes a memory cell connected to two or more bit lines. To reduce the overall wire resistance, the bit lines are connected in parallel. This parallel arrangement increases the likelihood of successfully programming the memory cell.

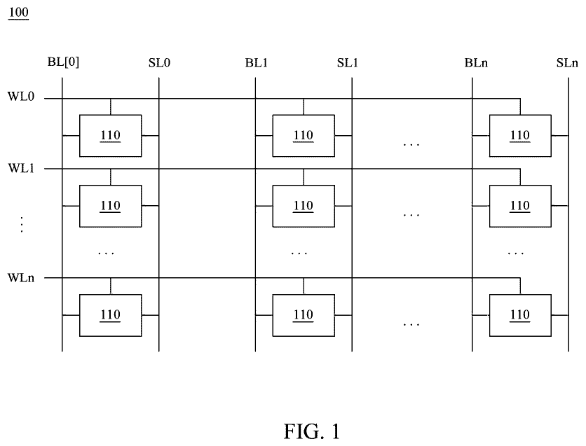

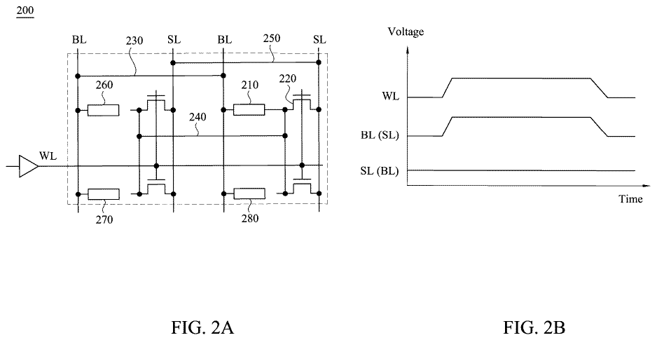

FIG. 1 is a schematic circuit diagram illustrating an exemplary memory device in accordance with various embodiments of the present disclosure. The example memory device 100, e.g., an OTP memory device, includes a plurality of memory cells 110, a plurality of word lines (WL0-WLn), and a plurality of bit lines (BL0-BLn). An OTP memory device is a type of memory device that permanently stores bits of data, which cannot be altered once written. For example, each memory cell 110 includes an OTP element. In this exemplary embodiment, the OTP element includes an anti-fuse (e.g., anti-fuse 210 in FIG. 2A) that is initially non-conductive, representing a logical ‘0’ (or ‘1’). When programmed, the anti-fuse becomes conductive, e.g., by applying a high voltage or current, representing a programmed bit, e.g., a logical ‘1’ (or ‘0’).

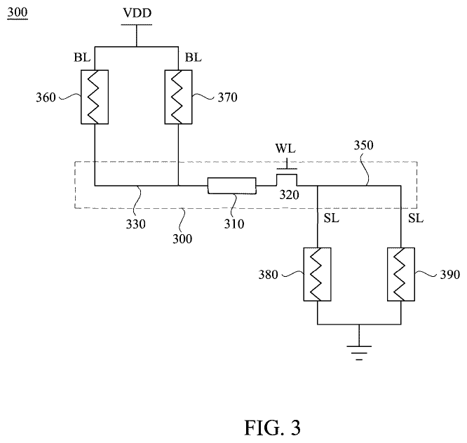

The memory cells 110 may be arranged in an array of rows and columns. The memory cells 110 in each row are connected to their respective word line (WL0-WLn). Similarly, the memory cells 110 in each column are connected to their respective bit line (BL0-BLn). For example, each bit line (BL0-BLn) is connected between a voltage node (e.g., VDD node in FIG. 3) and the memory cells 110 in the respective column. In this exemplary embodiment, the memory device 100 further includes a plurality of source lines (SL0-SLn), each connecting the memory cells 110 in a column to a ground (or VSS) node.

The memory cell 110 stores a bit, either a logical ‘0’ or ‘1’, and undergoes a permanent and irreversible change when written or programmed. For example, this change occurs when a high voltage, i.e., a programming voltage, is applied to a corresponding bit line (BL0-BLn), ensuring the memory cell 110 cannot be reprogrammed (i.e., the bit stored therein cannot be overwritten). The word line (WL0-WLn) enables access to a corresponding memory cell 110 by asserting it during read and write operations.

In certain embodiments, the memory cells 110 in each column is connected between two or more bit lines, e.g., two or more bit lines (BL[0]), connected in parallel and two or more source lines, e.g., two or more source lines (SL[0]), connected in parallel. This parallel configuration reduces the total wire resistance of the bit lines (BL[0]), as well as the total wire resistance of source lines (SL[0]), minimizing the wire resistance that opposes current flow. The lower resistance in the wiring may help ensure that enough programming voltage or current can be delivered reliably to the memory cell 110, increasing the likelihood of successfully programming the anti-fuse to its conductive state.

To read a memory cell 110, the word line, e.g., word line (WL[0]) corresponding to the desired row is asserted, e.g., by applying a high word line (WL) signal thereto. The bit line, e.g., bit line BL[0], is then used to detect the state of memory cell 110. If the anti-fuse has been programmed, it will exhibit a distinct electrical characteristic, such as reduced resistance or increased current flow, indicating that a conductive path has been established. This characteristic corresponds to the programmed logical state, representing a logical ‘1’ (or ‘0’). The increase in current flow or decrease in resistance is due to the creation of the conductive path across the anti-fuse, which is permanent and non-reprogrammable. Conversely, if the anti-fuse remains unprogrammed (i.e., intact), it retains its high resistance state and the memory cell 110 exhibits a different electrical signal corresponding to a logical ‘0’ (or ‘1’). The absence of a conductive path results in a higher resistance or lower current flow. The programmed data is read by sensing the voltage or current levels on the bit line (BL[0]), which reflects the state of the memory cell 110. Through further processing, e.g., amplification, of these voltage or current levels, the bit stored in the memory cell 110 can be accurately retrieved, determining whether the memory cell 110 holds a logical ‘1’ or ‘0’.

In an alternative embodiment, the OTP element includes a fuse. Unlike an anti-fuse, which creates a conductive path when programmed, a fuse is initially conductive and becomes non-conductive when “blown” or programmed.

FIG. 2A is a schematic circuit diagram illustrating an exemplary memory cell 200 in accordance with various embodiments of the present disclosure. As illustrated in FIG. 2A, the example memory cell 200, e.g., memory cell 110, is in the form of a four-transistor, one-resistor (4T1R) memory cell and includes one OTP element 210 and four select transistors 220 (for simplicity, only one of the select transistors is labeled in FIG. 2A). The OTP element 210 has a first OTP element terminal connected to two or more bit lines (BLs). For example, each bit line (BL) is connected to a voltage node, e.g., VDD node of FIG. 3. The memory cell 200 further includes an interconnect line 230 that connects the bit lines (BLs) in parallel. The first OTP element terminal of the OTP element 210 is connected to the interconnect line 230.

In this exemplary embodiment, the OTP element 210 includes an anti-fuse in a form of a magnetic tunnel junction (MTJ), a dielectric breakdown anti-fuse, a phase-change material-based anti-fuse, a resistive-switching element, any other type of anti-fuse technology that transitions from a high-resistance to a low-resistance state when programmed or written, or a combination thereof.

The select transistor 220, in this exemplary embodiment, is a field-effect transistor (FET) and has a gate terminal, a first source/drain terminal, and a second source/drain terminal. The gate terminals are connected to each other and to the word line (WL). The first source/drain terminals of the select transistor 220 are connected to each other and to the second OTP element terminal of the OTP element 210. For example, the memory cell 200 further includes an interconnect line 240 that connects the first source/drain terminals to each other. The second OTP element terminal of the OTP element 210 is connected to the interconnect line 240. The second source/drain terminals of the select transistors 220 are connected to each other and to two or more source lines (SLs). For example, each source line (SL) is connected to a ground (or VSS) node. The memory cell 200 further includes an interconnect line 250 that connects the source lines (SLs) in parallel. The second source/drain terminals of the select transistors 220 are connected to each other and to the interconnect line 250.

In some embodiments, each select transistor 220 is an n-type metal-oxide-semiconductor FET. In other embodiments, at least one of the select transistors 220 is a p-type metal-oxide-semiconductor FET. In an alternative embodiment, the memory cell 200 includes a planar transistor, a gate-all-around (GAA) transistor, a back-end metal-oxide-semiconductor, any suitable transistor, or a combination thereof.

From the above description, the memory cell 200 uses a combination of an OTP element 210 and a select transistor 220 to permanently store a bit therein by altering the state of the OTP element 210. For example, before programming, the OTP element 210 is intact, i.e., there is no conductive path through it, resulting in a high resistance. In this state, the OTP element 210 behaves like an open circuit, preventing significant current flow. The absence of a conductive path indicates that a logical ‘0’ (or ‘1’) is stored in the memory cell 200. During a write or programming operation, the select transistor 220 is activated by a high (or low) word line (WL) signal (‘1’) at the word line (WL), enabling access to the memory cell 200. For example, FIG. 2B is a schematic timing diagram illustrating an exemplary relationship among a word line (WL) signal, a bit line (BL) signal, and a source line (SL) signal in accordance with various embodiments of the present disclosure. The memory cell 200 is then connected between the bit lines (BLs) and the source lines (SLs). A programming voltage, i.e., a higher voltage, is then applied across the bit lines (BLs), the memory cell 200, and the source lines (SLs), resulting in a current flowing therethrough. This current may permanently alter the structure of the OTP element 210, e.g., creating a conductive path and reducing its resistance to low (or programmed) state. This programmed state represents a logical ‘1’ (or ‘0’) being stored in the memory cell 200. Because the bit lines (BLs) are connected in parallel, the total wire resistance of the bit lines (BLs) is reduced. Additionally, because the source lines (SLs) are connected in parallel, the total wire resistance of the source lines (SLs) is also reduced.

This reduction in wire resistance improves the efficiency of current flow, thereby increasing the likelihood of successfully programming the memory cell 200.

During a read operation, a high (or low) word line (WL) signal at the word line (WL) activates the select transistor 220 and connects the memory cell 200 between the bit lines (BLs) and the source lines (SLs). Instead of the higher programming voltage used for programming, a much lower read voltage is applied across the bit lines (BLs), the memory cell 200, and the source lines (SLs). If the OTP element 210 is programmed (i.e., it is in a low resistance state), a current flows through it and a sense amplifier connected to the memory cell 200 interprets the bit stored in the memory cell 200 as a logical ‘1’ (or ‘0’). Otherwise, i.e., the OTP element 210 is non-conductive and substantially no or no current flows through it. In this state, the sense amplifier interprets the bit stored in the memory cell 200 as a logical ‘0’ (or ‘1’).

In an alternative embodiment, the source line (SL) is connected to the VDD node, while the bit line (BL) is connected the ground (or VSS) node. In some embodiments, the memory cell 200 is connected between a plurality bit lines (BL) connected in parallel and a single source line (SL). In other embodiments, the memory cell 200 is connected between a single bit line (BL) and a plurality of source lines (SLs) connected in parallel.

In certain embodiments, the memory cell 200 further includes one or more floating OTP elements 260-280. Each OTP element 260-280 has a first OTP element terminal connected to the bit line (BL) and a second, floating OTP element terminal (i.e., the second OTP element terminal has no electrical connection to the memory cell 200).

Although the memory cell 200 is exemplified as a 4T1R memory cell, it should be understood that, after reading this disclosure, the memory cell 200 may include any number of OTP elements and select transistors, such as 1T1R, 2T2R, 1T1C (one transistor, one capacitor), 1T1MTJ (one transistor, one magnetic tunnel junction), and the like.

In an alternative embodiment, the OTP element 210 includes a fuse. Unlike an anti-fuse, which creates a conductive path when programmed, a fuse is initially conductive and becomes non-conductive when “blown” or programmed.

FIG. 3 is a schematic circuit diagram illustrating another exemplary memory cell 300 in accordance with various embodiments of the present disclosure. As illustrated in FIG. 3, the example memory cell 300, e.g., memory cell 200, includes an OTP element 310 and a select transistor 320. The OTP element 210 has a first OTP element terminal connected to two or more bit lines (BLs). For example, each bit line (BL) is connected to a voltage (VDD) node. The memory cell 300 further includes an interconnect line 330 that connects the bit lines (BLs) in parallel. The first OTP element terminal of the OTP element 310 is connected to the interconnect line 330. The select transistor 320 has a gate terminal, a first source/drain terminal, and a second source/drain terminal. The gate terminal is connected to the word line (WL). The first source/drain terminal of the select transistor 320 is connected to the second OTP element terminal of the OTP element 310. The second source/drain terminal of the select transistor 320 is connected to two or more source lines (SLs). For example, each source line (SL) is connected to a ground (or VSS) node. The memory cell 300 further includes an interconnect line 350 that connects the source lines (SLs) in parallel. The second source/drain terminal of the select transistor 320 is connected to the interconnect line 350. In this exemplary embodiment, the OTP element 310 is an anti-fuse.

From the above description, with further reference to FIG. 2B, during a write or programming operation, the select transistor 320 is activated by a high (or low) word line (WL) signal at the word line (WL), enabling access to the memory cell 300. At this time, the memory cell 300 is connected between the bit lines (BLs) and the source lines (SLs). A programming voltage is then applied across the bit lines (BLs), the memory cell 200, and the source lines (SLs), resulting in a current flowing therethrough. This current may permanently alter the structure of the OTP element 310, e.g., creating a conductive path and reducing its resistance to low (or programmed) state. This programmed state represents a logical ‘1’ (or ‘0’) being stored in the memory cell 300. Because the bit lines (BLs) are connected in parallel, the total wire resistance, e.g., the equivalent wire resistances 360, 370, of the bit lines (BLs), is reduced. Additionally, because the source lines (SLs) are connected in parallel, the total wire resistance, e.g., the equivalent wire resistances 380, 390, of the source lines (SLs) is also reduced. This reduction in wire resistance improves the efficiency of current flow, thereby increasing the likelihood of successfully programming the memory cell 300.

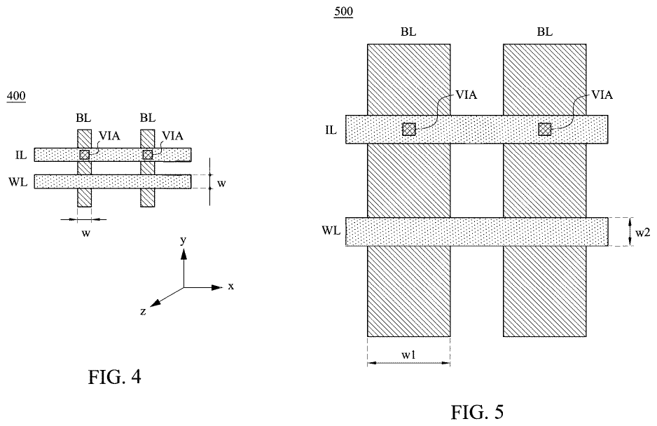

FIG. 4 is a schematic layout diagram illustrating exemplary conductive lines of a memory cell (e.g., memory cell 200) in accordance with various embodiments of the present disclosure. As illustrated in FIG. 4, the example layout 400 includes two or more bit lines (BLs), a word line (WL), an interconnect line (IL), and two or more vias (VIAs). The bit lines (BLs) are spaced apart along a first direction (x) and each extend in a second direction (y) transverse to the first direction (x). In certain embodiments, the bit lines (BLs) are formed in the same metal layer, e.g., metal layer (M6).

The word line (WL) and the interconnect line (IL) each extend in the first direction (x) and are spaced apart along the second direction (y). In certain embodiments, the word line (WL) and the interconnect line (IL) are formed in the same metal layer(s), e.g., metal layer (M1 and/or M7).

Each of the vias (VIAs) extends in a third direction (z) transverse to the first and second directions (x, y) and connects a respective one of the bit lines (BLs) to the interconnect line (IL). Because the bit lines (BLs) are connected to the same interconnect line (IL), the bit line (BLs) are connected in parallel. This parallel connection reduces the total wire resistance of the bit lines (BLs), thereby increasing the likelihood of successfully programming the memory cell 200.

In certain embodiments, the layout 400 further includes two or more source lines (e.g., SLs of FIG. 2A) connected in parallel. The construction of the source lines (SLs) is similar to that described above in connection with the bit lines (BLs). Accordingly, a detailed description of the source lines (SLs) is omitted herein for the sake of brevity.

In this exemplary embodiment, the bit lines (BLs), the source lines (SLs), the word line (WL), the interconnect line (IL), and the vias (VIAs) are formed from a conductive material, such as copper (Cu), aluminum (AL), other suitable metals, or their alloys, which are deposited over the memory cell 200 to establish an electrical connection.

In some embodiments, the bit line (BL) (and/or the source line SL) has substantially the same width (w) as the word line (WL). In such some embodiments, the interconnect line (IL) may have substantially the same width (W) as the word line (WL). In other embodiments, the bit line (BL) (and/or the source line SL) may have a different width than the word line (WL). For example, FIG. 5 is a schematic layout diagram illustrating another exemplary conductive lines of a memory cell (e.g., memory cell 200) in accordance with various embodiments of the present disclosure. As illustrated in FIG. 5, the bit line (BL) (and/or the source line SL) has a width (w1) greater than a width (w2) of the word line (WL). The construction as such further reduces the total wire resistance of the bit lines (BLs) and/or the total wire resistance of the source lines (SLs).

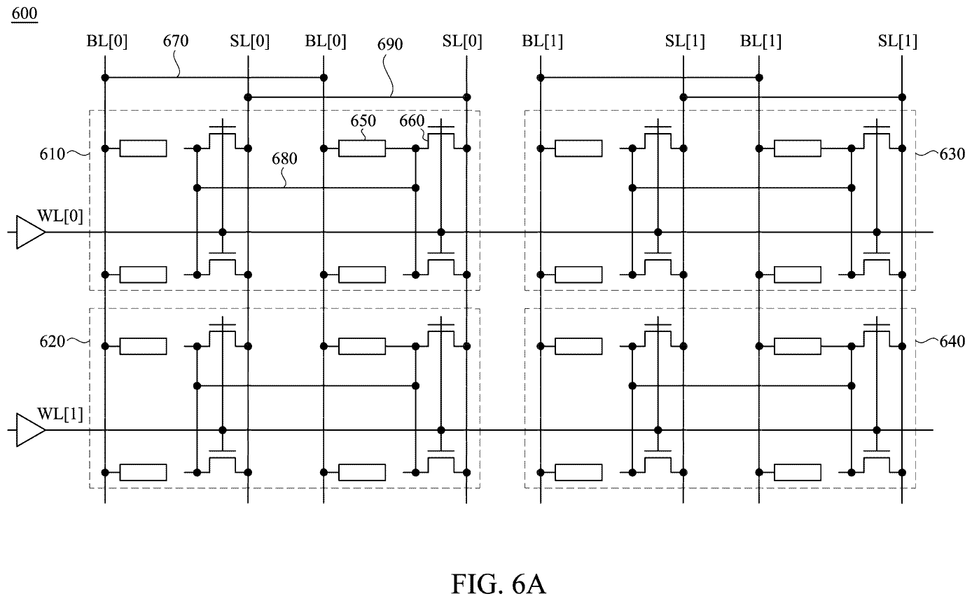

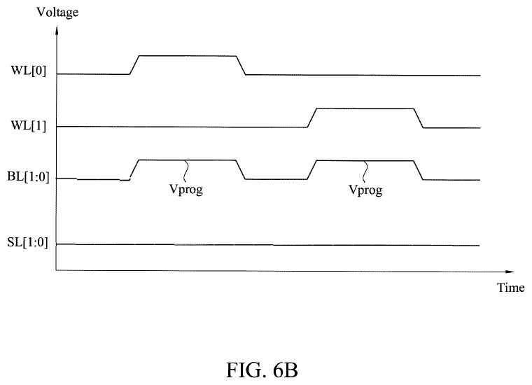

FIG. 6A is a schematic circuit diagram illustrating another exemplary memory device in accordance with various embodiments of the present disclosure. As illustrated in FIG. 6A, the example memory device 600, e.g., memory device 100, includes a plurality of memory cells, e.g., memory cells 610-640, arranged in an array of rows and columns. The memory cells 610-640 in each row are connected to the respective word line (WL[0], WL[1]). Similarly, the memory cells 610-640 in each column are connected between the respective bit line (BL[0], BL[1]) and the respective source line (SL[0], SL[1]). Because the memory cells 610-640 are similar in construction and operation, only the memory cell 610 will be described. The memory cell 610, e.g., memory cell 200, is in the form of a 4T1R memory cell and includes one OTP element 650 and four select transistors 660. For simplicity, only one of the select transistors 660 is labeled in FIG. 6A. The OTP element 650 has a first OTP element terminal connected to two or more bit lines (BL[0]). For example, each bit line (BL[0]) is connected to a VDD node. The memory cell 610 further includes an interconnect line 670 that connects the bit lines (BL[0]) in parallel. The first OTP element terminal of the OTP element 650 is connected to the interconnect line 670.

The select transistor 660 has a gate terminal, a first source/drain terminal, and a second source/drain terminal. The gate terminals are connected to each other and to the word line (WL[0]). The first source/drain terminals of the select transistor 660 are connected to each other and to the second OTP element terminal of the OTP element 650. For example, the memory cell 610 further includes an interconnect line 680 that connects the first source/drain terminals of the select transistors 660 to each other. The second OTP element terminal of the OTP element 650 is connected to the interconnect line 680. The second source/drain terminals of the select transistors 660 are connected to each other and to two or more source lines (SL[0]). For example, each source line (SL[0]) is connected to a ground (or VSS) node. The memory cell 610 further includes an interconnect line 690 that connects the source lines (SLs) in parallel. The second source/drain terminals of the select transistors 660 are connected to each other and to the interconnect line 690.

From the above description, because the bit lines (BL[0]) are connected in parallel, the total wire resistance of the bit lines (BL[0]s) is reduced. Additionally, because the source lines (SL[0]s) are connected in parallel, the total wire resistance of the source lines (SL[0]s) is also reduced. This reduction in wire resistance improves the efficiency of current flow, thereby increasing the likelihood of successfully programming the memory cell 610.

During a write or programming operation, the select transistor 650 is activated by a high word line (WL[0]) signal (‘1’) at the word line (WL[0]), enabling access to the memory cell 610. For example, FIG. 6B is a schematic timing diagram illustrating an exemplary relationship among a word line (WL) signal, a bit line (BL) signal, and a source line (SL) signal in accordance with various embodiments of the present disclosure. The memory cell 610 is then connected between the bit lines (BL[0]s) and the source lines (SL[0]s). A programming voltage (Vprog), i.e., a higher voltage, is then applied across the bit lines (BL[0]s), the memory cell 610, and the source lines (SL[0]s), resulting in a current flowing therethrough. This current may permanently alter the structure of the OTP element 650, e.g., creating a conductive path and reducing its resistance to low (or programmed) state. This programmed state represents a logical ‘1’ (or ‘0’) being stored in the memory cell 610. Because the bit lines (BL[0]s) are connected in parallel, the total wire resistance of the bit lines (BL[0]s) is reduced. Additionally, because the source lines (SL[0]s) are connected in parallel, the total wire resistance of the source lines (SL[0]s) is also reduced. This reduction in wire resistance improves the efficiency of current flow, thereby increasing the likelihood of successfully programming the memory cell 610.

During a read operation, a high word line (WL[0]) signal at the word line (WL[0]) activates the select transistor 660 and connects the memory cell 610 between the bit lines (BL[0]s) and the source lines (SL[0]s). Instead of the higher programming voltage used for programming, a much lower read voltage is applied across the bit lines (BL[0]s), the memory cell 610, and the source lines (SL[0]s). If the OTP element 210 is programmed (i.e., it is in a low resistance state), a current flows through it and a sense amplifier connected to the memory cell 610 interprets the bit stored in the memory cell 610 as a logical ‘1’ (or ‘0’). Otherwise, i.e., the OTP element 650 is non-conductive and substantially no or no current flows through it. In this state, the sense amplifier interprets the bit stored in the memory cell 610 as a logical ‘0’ (or ‘1’).

The read and write operations on the other memory cells are similar to those described above in connection with memory cell 610. For example, the next write operation on another memory cell 620-640 asserts the word line (WL[1]) with a high word line (WL[1]) signal, while the programming voltage (Vprog) is applied across the bit lines (BL[1]s), the memory cell 620-640, and the source lines (SL[1]s).

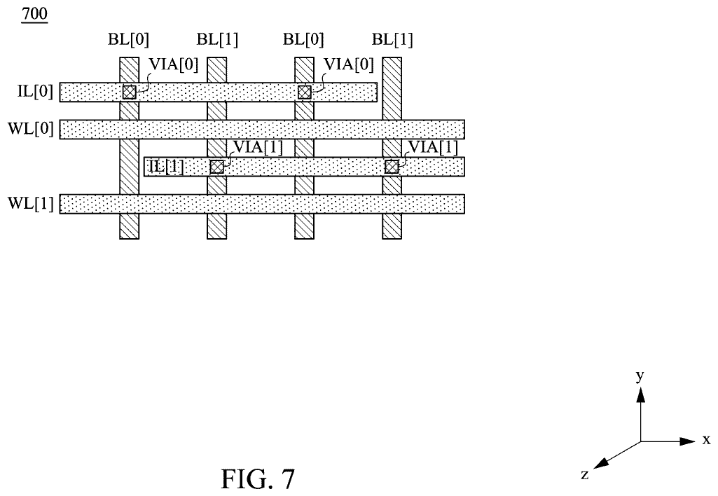

FIG. 7 is a schematic layout diagram illustrating another exemplary conductive lines of a memory device (e.g., memory device 600) in accordance with various embodiments of the present disclosure. As illustrated in FIG. 7, the example layout 700 includes two or more bit lines (BL[0]), two or more bit lines (BL[1]), a plurality of word lines (e.g., WL[0] and WL[1]), a plurality of interconnect lines (e. g, IL[0] and IL[1]), two or more vias VIA[0], and two or more VIA[1]. The bit lines (BL[0], BL[1]) are alternately arranged along a first direction (x) and each extend in a second direction (y) transverse to the first direction (x).

The word lines (WL[0], WL[1]) and the interconnect lines (IL[0], IL[1]) each extend in the first direction (x) and are alternately arranged along the second direction (y). In certain embodiments, the word lines (WL[0], WL[1]) and the interconnect lines (IL[0], IL[1]) are formed in the same metal layer(s), e.g., metal layer (M1 and/or M7).

Each of the vias (VIA[0]) extends in a third direction (z) transverse to the first and second directions (x, y) and connects a respective one of the bit lines (BL[0]) to the interconnect line (IL[0]). Similarly, each of the vias (VIA[1]) extends in the third direction (z) and connects a respective one of the bit lines (BL[1]) to the interconnect line (IL[1]). Because the bit lines (BL[0], BL[1]) are connected to the same interconnect line (IL[0], IL[1]), the bit line (BL[0], BL[1]) are connected in parallel. This parallel connection reduces the total wire resistance of the bit lines (BL[0], BL[1]), thereby increasing the likelihood of successfully programming the memory cell 200.

Furthermore, because the bit lines (BL[0], BL[1]) are alternately arranged along a first direction (x) and because the word lines (WL[0], WL[1]) and the interconnect lines (IL[0], IL[1]) are alternately arranged along the second direction (y), such a construction increases the distances between vias (VIA[0], VIA[1]), thereby preventing violations of via-spacing requirements.

In certain embodiments, the layout 700 further includes two or more source lines (e.g., SL[0] of FIG. 6A) connected in parallel and two or more source lines (e.g., SL[1] of FIG. 6A) also connected in parallel. The construction of the source lines (SL[0], SL[1]) is similar to that described above in connection with the bit lines (BL[0], BL[1]). Accordingly, a detailed description of the source lines (SL[0], SL[1]) is omitted herein for the sake of brevity.

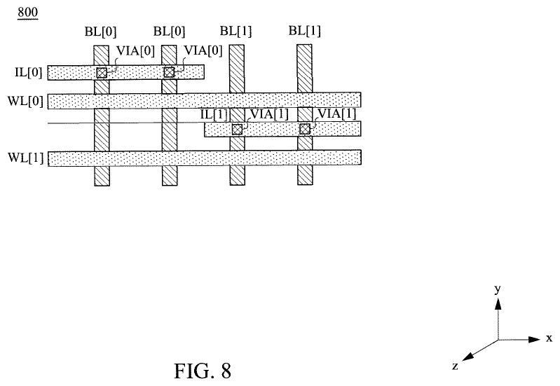

FIG. 8 is a schematic layout diagram illustrating another exemplary conductive lines of a memory device (e.g., memory device 600) in accordance with various embodiments of the present disclosure. As illustrated in FIG. 8, the example layout 800 includes a two or more bit lines BL[0], two or more bit lines BL[1], a plurality of word lines (e.g., WL[0] and WL[1]), a plurality of interconnect lines (e.g., IL[0] and IL[1]), two or more vias VIA[0], and two or more VIA[1]. The bit lines (BL[0], BL[1]) are alternately arranged along a first direction (x) and each extend in a second direction (y) transverse to the first direction (x).

The word lines (WL[0], WL[1]) and the interconnect lines (IL[0], IL[1]) each extend in the first direction (x) and are alternately arranged along the second direction (y). In certain embodiments, the word lines (WL[0], WL[1]) and the interconnect lines (IL[0], IL[1]) are formed in the same metal layer(s), e.g., metal layer (M1 and/or M7).

Each of the vias (VIA[0]) extends in a third direction (z) transverse to the first and second directions (x, y) and connects a respective one of the bit lines (BL[0]) to the interconnect line (IL[0]). Similarly, each of the vias (VIA[1]) extends in the third direction (z) and connects a respective one of the bit lines (BL[1]) to the interconnect line (IL[1]). Because the bit lines (BL[0], BL[1]) are connected to the same interconnect line (IL[0], IL[1]), the bit lines (BL[0], BL[1]) are connected in parallel. This parallel connection reduces the total wire resistance of the bit lines (BL[0], BL[1]), thereby increasing the likelihood of successfully programming the memory cell 200.

Furthermore, because the word lines (WL[0], WL[1]) and the interconnect lines (IL[0], IL[1]) are alternately arranged along the second direction (y), such a construction increases the distances between the vias (VIA[0], VIA[1]). Such increased in spacing helps to prevent violations of via-spacing requirements.

In certain embodiments, the layout 800 further includes two or more source lines (e.g., SL[0], SL[1] of FIG. 6A) connected in parallel. The construction of the source lines (e.g., SL[0]) and SL[1]) is similar to that described above in connection with the bit lines (BL[0], BL[1]). Accordingly, a detailed description of the source lines (SL[0], SL[1]) is omitted herein for the sake of brevity.

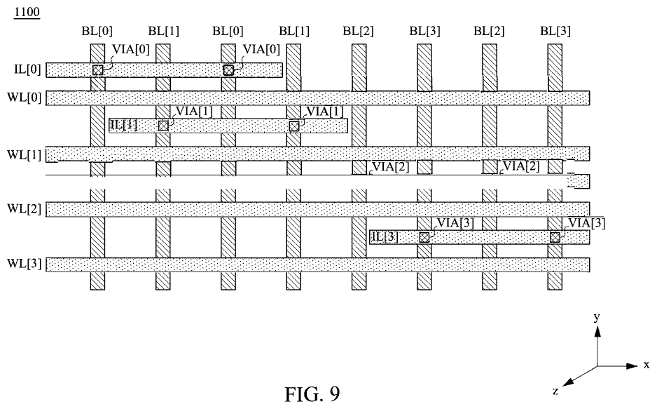

FIG. 9 is a schematic layout diagram illustrating another exemplary conductive lines of a memory cell in accordance with various embodiments of the present disclosure. As illustrated in FIG. 9, the example layout 900 includes two or more bit lines (BL[0]-BL[3]), a plurality of word lines (e.g., word lines WL[0]-WL[3]), a plurality of interconnect lines (e.g., IL[0]-IL[3]), two or more vias (VIA[0]-VIA[3]). The bit lines (BL[0]-BL[3]) are alternately arranged along a first direction (x) and each extend in a second direction (y) transverse to the first direction (x).

The word lines (WL[0]-WL[3]) and the interconnect lines (IL[0]-IL[3]) each extend in the first direction (x) and are alternately arranged along the second direction (y). In certain embodiments, the word lines (WL[0]-WL[3]) and the interconnect lines (IL[0]-IL[3]) are formed in the same metal layer(s), e.g., metal layer (M1 and/or M7).

Each of the vias (VIA[0]) extends in a third direction (z) transverse to the first and second directions (x, y) and connects a respective one of the bit lines (BL[0]) to the interconnect line (IL[0]). Similarly, each of the vias (VIA[1]-VIA[3]) extends in the third direction (z) and connects a respective one of the bit lines (BL[1]-BL[3]) to the interconnect line (IL[1]-IL[3]). Because the bit lines (BL[0]-BL[3]) are connected to the same interconnect line (IL[0]-IL[3])), the bit line (BL[0]-BL[3]) are connected in parallel. This parallel connection reduces the total wire resistance of the bit lines (BL[0]-BL[3]), thereby increasing the likelihood of successfully programming the memory cell.

Furthermore, because the bit lines (BL[0]-BL[3]) are alternately arranged along a first direction (x) and because the word lines (WL[0]-WL[3]) and the interconnect lines (IL[0]-IL[3]) are alternately arranged along the second direction (y), such a construction increases the distances between vias (VIA[0], VIA[1]). Such increased in spacing helps to prevent violations of via-spacing requirements.

In certain embodiments, the layout 900 further includes two or more source lines (e.g., SL[0]-SL[3]) connected in parallel. The construction of the source lines (SL[0]-SL[3]) is similar to that described above in connection with the bit lines (BL[0]-BL[3]). Accordingly, a detailed description of the source lines (SL[0]-SL[3]) is omitted herein for the sake of brevity.

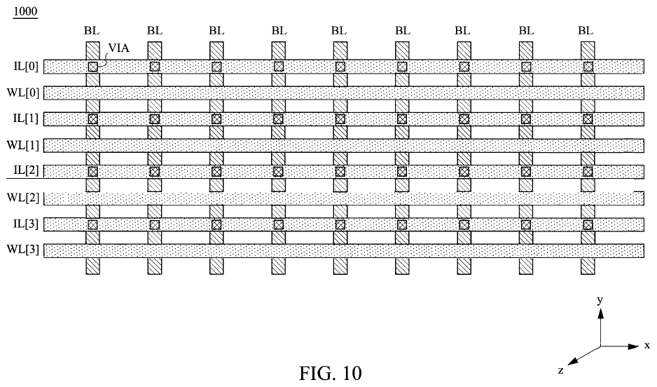

FIG. 10 is a schematic layout diagram illustrating another exemplary conductive lines of a memory cell in accordance with various embodiments of the present disclosure. As illustrated in FIG. 10, the example layout 1000 includes two or more bit lines (BLs), a plurality of word lines (e.g., word lines WL[0]-WL[3]), a plurality of interconnect lines (e.g., interconnect lines IL[0]-IL[3]), and two or more vias (VIAs). For simplicity, only one of the vias (VIAs) is labeled in FIG. 10. The bit lines (BLs) are arranged along a first direction (x) and each extend in a second direction (y) transverse to the first direction (x).

The word lines (WL[0]-WL[3]) and the interconnect lines (IL[0]-IL[3]) each extend in the first direction (x) and are alternately arranged along the second direction (y). In certain embodiments, the word lines (WL[0]-WL[3]) and the interconnect lines (IL[0]-IL[3]) are formed in the same metal layer(s), e.g., metal layer (M1 and/or M7).

Each of the vias (VIAs) extends in a third direction (z) transverse to the first and second directions (x, y) and connects a respective one of the bit lines (BLs) to the interconnect line (IL[0]-IL[3]). Because the bit lines (BLs) are connected to the same interconnect line (IL[0]-IL[3]), the bit lines (BLs) are connected in parallel. This parallel connection reduces the total wire resistance of the bit lines (BLs), thereby increasing the likelihood of successfully programming the memory cell.

Furthermore, because the word lines (WL[0]-WL[3]) and the interconnect lines (IL[0]-IL[3]) are alternately arranged along the second direction (y), such a construction increases the distances between vias (VIAs) along the second direction (y). Such increased in spacing helps to prevent violations of via-spacing requirements.

In certain embodiments, the layout 1000 further includes two or more source lines (e.g., SLs) connected in parallel. The construction of the source lines (SLs) is similar to that described above in connection with the bit lines (BLs). Accordingly, a detailed description of the source lines SLs is omitted herein for the sake of brevity.

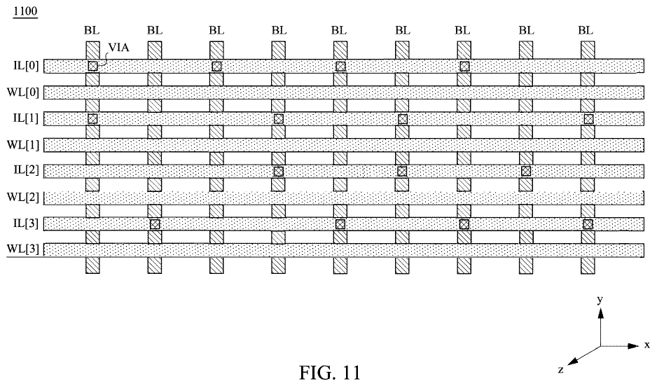

FIG. 11 is a schematic layout diagram illustrating another exemplary conductive lines of a memory device in accordance with various embodiments of the present disclosure. As illustrated in FIG. 11, the example layout 1100 includes two or more bit lines (BLs), a plurality of word lines (e.g., word lines WL[0]-WL[3]), a plurality of interconnect lines (e.g., interconnect lines IL[0]-IL[3]), and two or more vias (VIAs). For simplicity, only one of the vias (VIAs) is labeled in FIG. 11. The bit lines (BLs) are arranged along a first direction (x) and each extend in a second direction (y) transverse to the first direction (x).

The word lines (WL[0]-WL[3]) and the interconnect lines (IL[0]-IL[3]) each extend in the first direction (x) and are alternately arranged along the second direction (y). In certain embodiments, the word lines (WL[0]-WL[3]) and the interconnect lines (IL[0]-IL[3]) are formed in the same metal layer(s), e.g., metal layer (M1 and/or M7).

Each of the vias (VIAs) extends in a third direction (z) transverse to the first and second directions (x, y) and connects an alternate one of the bit lines (BLs) to the interconnect line (IL[0]-IL[3]). Because the bit lines (BLs) are connected to the same interconnect line (IL[0]-IL[3]), the bit lines (BLs) are connected in parallel. This parallel connection reduces the total wire resistance of the bit lines (BLs), thereby increasing the likelihood of successfully programming the memory cells, as described above.

Furthermore, because alternate bit lines are connected to the interconnect line (IL[0]-IL[3]) and because the word lines (WL[0]-WL[3]) and the interconnect lines (IL[0]-IL[3]) are alternately arranged along the second direction (y), such a construction increases the distances between vias (VIAs) along the first and second directions (x, y). Such increased in spacing helps to prevent violations of via-spacing requirements.

In certain embodiments, the layout 1100 further includes two or more source lines (e.g., SLs) connected in parallel. The construction of the source lines (SLs) is similar to that described above in connection with the bit lines (BLs). Accordingly, a detailed description of the source lines (SLs) is omitted herein for the sake of brevity.

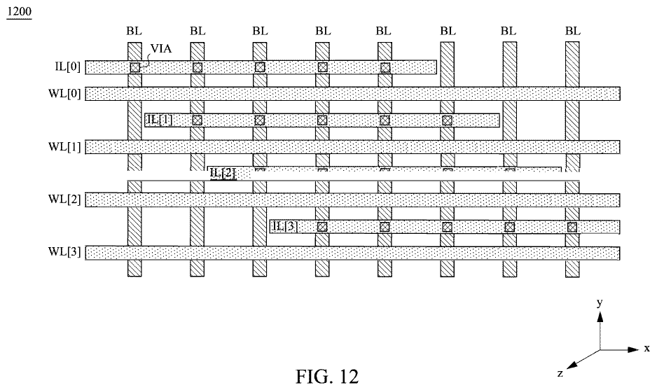

FIG. 12 is a schematic layout diagram illustrating another exemplary conductive lines of a memory device in accordance with various embodiments of the present disclosure. As illustrated in FIG. 12, the example layout 1200 includes two or more bit lines (BLs), a plurality of word lines (e.g., WL[0]-WL[3]), a plurality of interconnect lines (e.g., IL[0]-IL[3]), and two or more vias (VIAs). For simplicity, only one of the vias (VIAs) is labeled in FIG. 12. The bit lines (BLs) are arranged along a first direction (x) and each extend in a second direction (y) transverse to the first direction (x).

The word lines (WL[0]-WL[3]) and the interconnect lines (IL[0]-IL[3]) each extend in the first direction (x) and are alternately arranged along the second direction (y). In certain embodiments, the word lines (WL[0]-WL[3]) and the interconnect lines (IL[0]-IL[3]) are formed in the same metal layer(s), e.g., metal layer (M1 and/or M7).

Each of the vias (VIAs) extends in a third direction (z) transverse to the first and second directions (x, y) and connects a respective one of subsets of the bit lines (BLs) to the interconnect line (IL[0]-IL[3]). Because the bit lines (BLs) are connected to the same interconnect line (IL[0]-IL[3]), the bit lines (BLs) are connected in parallel. This parallel connection reduces the total wire resistance of the bit lines (BLs), thereby increasing the likelihood of successfully programming the memory cells, as described above.

Furthermore, because a subset of bit lines are connected to the interconnect line (IL[0]-IL[3]) and because the word lines (WL[0]-WL[3]) and the interconnect lines (IL[0]-IL[3]) are alternately arranged along the second direction (y), such a construction increases the distances between vias (VIAs) along the first and second directions (x, y). Such increased in spacing helps to prevent violations of via-spacing requirements.

In certain embodiments, the layout 1200 further includes two or more source lines (e.g., SLs) connected in parallel. The construction of the source lines (SLs) is similar to that described above in connection with the bit lines (BLs). Accordingly, a detailed description of the source lines (SLs) is omitted herein for the sake of brevity.

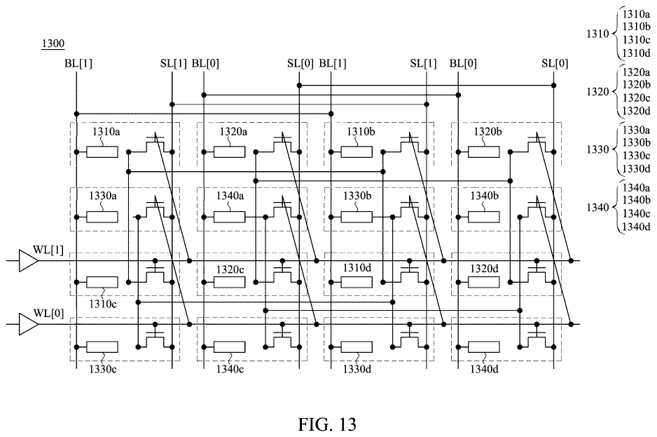

FIG. 13 is a schematic circuit diagram illustrating another exemplary memory device in accordance with various embodiments of the present disclosure. As illustrated in FIG. 13, the example memory device 1300 includes a plurality of memory cells (e.g., memory cells 1310-1340), each including cell portions 1310a-1310d, 1320a-1320d, 1330a-1330d, 1340a-1340d. In this exemplary embodiment, the cell portions 1310a-1310d, 1320a-1320d, 1330a-1330d, 1340a-1340d of one memory cell 1310-1340 are separated by the cell portions 1310a-1310d, 1320a-1320d, 1330a-1330d, 1340a-1340d of other memory cells 1310-1340. For example, the cell portions 1310a-1310d, 1320a-1320d, 1330a-1330d, 1340a-1340d are arranged in an array of rows and columns. The cell portions 1310a, 1310b, 1320a, 1320b are alternately arranged along the first row and each connected to a word line (WL[1]). The cell portions 1330a, 1330b, 1340a, 1340b are alternately arranged along the second row and each connected to a word line (WL[0]). The cell portions 1310c, 1310d, 1320c, 1320d are alternately arranged along the third row and each connected to the word line (WL[1]). The cell portions 1330c, 1330d, 1340c, 1340d are alternately arranged along the fourth row and each connected to the word line (WL[0]).

Similarly, the cell portions 1310a, 1310c, 1330a, 1330c are alternately arranged along the first column and each connected between two or more bit lines (BL[1]) and two or more source lines (SL[1]). The cell portions 1320a, 1320c, 1340a, 1340c are alternately arranged along the second column and each connected between two or more bit lines (BL[0]) and two or more source lines (SL[0]). The cell portions 1310b, 1310d, 1330b, 1330d are alternately arranged along the third column and each connected between two or more bit lines (BL[1]) and two or more source lines (SL[1]). The cell portions 1320b, 1320d, 1340b, 1340d are alternately arranged along the fourth column and each connected between two or more bit lines (BL[0]) and two or more source lines (SL[0]). The construction as such of the memory device 1330 simplifies the layout design of the conductive lines (e.g., bit lines, source lines, and word lines) of the memory device 1330.

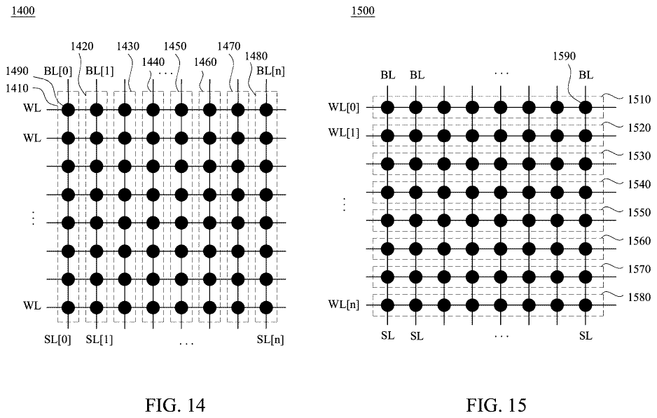

FIG. 14 is a schematic circuit diagram illustrating another exemplary memory device in accordance with various embodiments of the present disclosure. As illustrated in FIG. 14, the example memory device 1400 includes a plurality of memory cells, e.g., memory cells 1410-1480, each constituting a plurality of memory cells merged into a single memory cell. Because the memory cells 1410-1480 are similar in structure, only one (e.g., memory cell 1410) will be described. The memory cell 1410 includes a plurality of memory cells 1490. For simplicity, only one of the memory cells 1490 is labeled in FIG. 14. Each memory cell 1490 is connected to a plurality of word lines (WL) connected to each other and between two or more bit lines (BL[0]) connected in parallel and two or more source lines (SL[0]) connected in parallel. The construction as such of the memory device 1400 simplifies the layout design of the conductive lines (e.g., bit lines, source lines, and word lines) thereof.

In some embodiments, the memory cell 1410 is connected between a plurality bit lines (BL[0]) connected in parallel and a single source line (SL[0]). In other embodiments, the memory cell 1410 is connected between a plurality source lines (SL[0]) connected in parallel and a single bit line (BL[0]).

FIG. 15 is a schematic circuit diagram illustrating another exemplary memory device in accordance with various embodiments of the present disclosure. As illustrated in FIG. 15, the example memory device 1500 includes a plurality of memory cells, e.g., memory cells 1510-1580, each constituting a plurality of memory cells merged into a single memory cell. Because the memory cells 1510-1580 are similar in structure, only one (e.g., memory cell 1510) will be described. The memory cell 1510 includes a plurality of memory cells 1590. For simplicity, only one of the memory cells 1590 is labeled in FIG. 15. Each memory cell 1590 is connected to the respective word line (WL[0]-WL[n]) and between two or more bit lines (BLs) connected in parallel and two or more source lines (SL) connected in parallel. The construction as such of the memory device 1500 simplifies the layout design of the conductive lines (e.g., bit lines, source lines, and word lines) thereof.

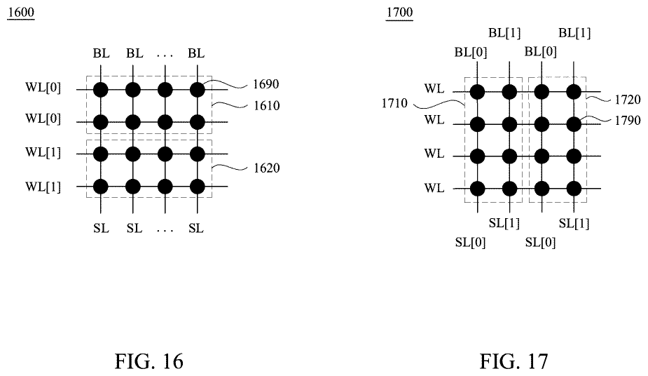

FIG. 16 is a schematic circuit diagram illustrating another exemplary memory device in accordance with various embodiments of the present disclosure. As illustrated in FIG. 16, the example memory device 1600 includes a plurality of memory cells, e.g., memory cells 1610, 1620, each constituting a plurality of memory cells merged into a single memory cell. Because the memory cells 1610, 1620 are similar in structure, only one (e.g., memory cell 1610) will be described. The memory cell 1610 includes a plurality of memory cells 1690. For simplicity, only one of the memory cells 1690 is labeled in FIG. 16. Each memory cell 1690 is connected to a plurality of word lines (WL[0]) connected to each other and between two or more bit lines (BLs) connected in parallel and two or more source lines (SL) connected in parallel. The construction as such of the memory device 1600 simplifies the layout design of the conductive lines (e.g., bit lines, source lines, and word lines) thereof.

FIG. 17 is a schematic diagram illustrating another exemplary memory device in accordance with various embodiments of the present disclosure. As illustrated in FIG. 17, the example memory device 1700 includes a plurality of memory cells, e.g., memory cells 1710, 1720, each constituting a plurality of memory cells merged into a single memory cell. Because the memory cells 1710, 1720 are similar in structure, only one (e.g., memory cell 1710) will be described. The memory cell 1710 includes a plurality of memory cells 1790. For simplicity, only one of the memory cells 1790 is labeled in FIG. 17. Each memory cell 1790 is connected to a plurality of word lines (WL) connected to each other and between two or more bit lines (BL[0]) connected in parallel and two or more source lines (SL[0]) connected in parallel. The construction as such of the memory device 1700 simplifies the layout design of the conductive lines (e.g., bit lines, source lines, and word lines) thereof.

In some embodiments, the memory cell 1710 is connected between a plurality bit lines (BL[0]) connected in parallel and a single source line (SL[0]). In other embodiments, the memory cell 1710 is connected between a plurality source lines (SL[0]) connected in parallel and a single bit line (BL[0]).

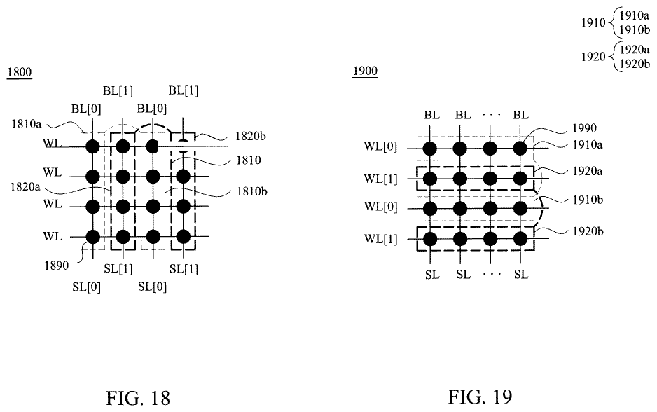

FIG. 18 is a schematic circuit diagram illustrating another exemplary memory device in accordance with various embodiments of the present disclosure. As illustrated in FIG. 18, the example memory device 1800 includes a plurality of memory cells, e.g., memory cells 1810, 1820, Each memory cell 1810, 1820 is divided into a plurality of cell portions, e.g., cell portions 1810a, 1810b, 1820a, 1820b. The cell portions 1810a, 1810b are separated by the cell portion 1820a. Similarly, the cell portions 1820a, 1820b are separated by the cell portion 1810b.

Furthermore, each memory cell 1810, 1820 constitutes a plurality of memory cells merged into a single memory cell. Because the memory cells 1810, 1820 are similar in structure, only one (e.g., memory cell 1810) will be described. The memory cell 1810 includes a plurality of memory cells 1890. For simplicity, only one of the memory cells 1890 is labeled in FIG. 18. Each memory cell 1890 is connected to a plurality of word lines (WL) connected to each other and between two or more bit lines (BL[0]) connected in parallel and two or more source lines (SL[0]) connected in parallel. The construction as such of the memory device 1800 simplifies the layout design of the conductive lines (e.g., bit lines, source lines, and word lines) thereof.

In some embodiments, the memory cell 1810, 1820 is connected between a plurality bit lines (BL[0], BL[1])) connected in parallel and a single source line (SL[0], SL[1]). In other embodiments, the memory cell 1810 is connected between a plurality source lines (SL[0], SL[1]) connected in parallel and a single bit line (BL[0], BL[1]). In some embodiments, the memory cell 1810 is connected between a plurality bit lines (BL[0], BL[1]) connected in parallel and a single source line (SL[0], SL[1]). In other embodiments, the memory cell 1810 is connected between a plurality source lines (SL[0], SL[1]) connected in parallel and a single bit line (BL[0], BL[1]).

FIG. 19 is a schematic diagram illustrating another exemplary memory device in accordance with various embodiments of the present disclosure. As illustrated in FIG. 19, the example memory device 1900 includes a plurality of memory cells, e.g., memory cells 1910, 1920. Each memory cell 1910, 1920 is divided into a plurality of cell portions, e.g., cell portions 1910a, 1910b, 1920a, 1920b. The cell portions 1910a, 1910b are separated by the cell portion 1920a. Similarly, the cell portions 1920a, 1920b are separated by the cell portion 1910b.

Furthermore, each memory cell 1910, 1920 constitutes a plurality of memory cells merged into a single memory cell. Because the memory cells 1910, 1920 are similar in structure, only one (e.g., memory cell 1910) will be described. The memory cell 1910 includes a plurality of memory cells 1990. For simplicity, only one of the memory cells 1990 is labeled in FIG. 19. Each memory cell 1990 is connected to a plurality of word lines (WL[0]) connected to each other and between two or more bit lines (BLs) connected in parallel and two or more source lines (SLs) connected in parallel. The construction as such of the memory device 1900 simplifies the layout design of the conductive lines (e.g., bit lines, source lines, and word lines) thereof.

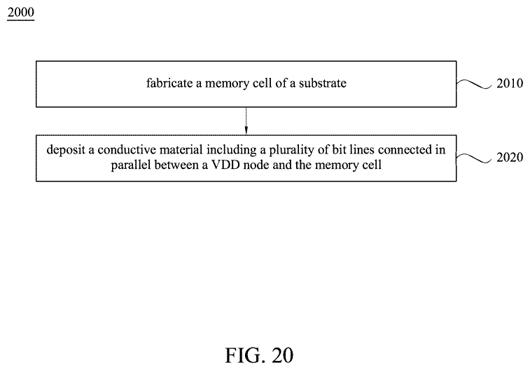

FIG. 20 is a flowchart of an exemplary method 2000 of manufacturing a memory device in accordance with various embodiments of the present disclosure. The example method 2000 will now be described with further reference to FIGS. 1-19 for ease of understanding. It is understood that method 2000 is applicable to structures other than those of FIGS. 1-19. Further, it is understood that additional operations can be provided before, during, and after the method 2000, and some of the operations described below can be replaced or eliminated, in an alternative embodiment of the method 2000.

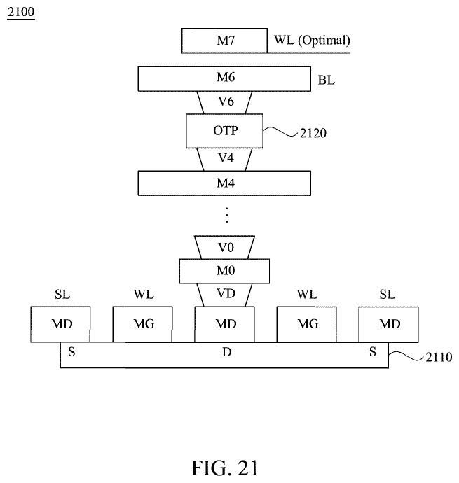

In operation 2010, the device manufacturing tool fabricate a memory cell (e.g., memory cell 110, 200, 300, 610) over a substrate. For example, FIG. 21 is a schematic sectional diagram illustrating another exemplary memory device 2100 in accordance with various embodiments of the present disclosure. As illustrated in FIG. 21, the example memory device 2100 (e.g., memory device 100-1900) includes a substrate 2110, a plurality of metal layers (M0-M7), and a plurality of vias (V0-V6). The substrate 2110 can be made from silicon, germanium, III-V semiconductors, other suitable substrate materials, and their alloys. At this time, the device manufacturing tool dopes the substrate 2110 to create source and regions (S, D) in active portions of the substrate 2110. The device manufacturing tool then deposits a conductive material to form a metal deposit (MD) over the top surfaces of the source and drain regions (S, D) and a metal gate (MG) over a top surface of a gate region between the source and drain regions (S, D). The source and drain regions (S, D) and the metal gate (MG) constitute a select transistor (e.g., select transistor 220, 320, 660).

Next, in operation 2020, the device manufacturing system deposits an additional conductive material to form the metal layers (e.g., metal layers M0-M7) stacked one above the other. For example, each metal layer (M0, M2) includes at least one source lines (SLs) that connects a select transistor to a ground (or VSS) node. The metal layer (M1, M3, M5, M7) includes a plurality of word lines (WLs), each connected to a respective metal gate (MG). The metal layer (M4, M6) includes a plurality of bit lines (BLs) connected between a VDD node and an OTP element 2120 (e.g., OTP element 260, 310, 650) of the memory cell. In this exemplary embodiment, the metal layer (M1, M3, M5, M7) further includes an interconnect line (e.g., interconnect line 230, 330, 670) that connects the bit lines (BLs) in parallel. The via (V0-V6) interconnects the metal layers (M0-M7). Examples of conductive materials include copper (Cu), aluminum (AL), other suitable metals, or their alloys.

In an embodiment, a memory device includes a plurality of memory cells, a word line, a plurality of bit lines, and a plurality of source lines. Each memory cell includes an one-time programmable (OTP) element and a plurality of select transistors. The word line is connected to gate terminals of the select transistors of a memory cell. The bit lines are connected in parallel between a first node and a first OTP element terminal of the OTP element of the memory cell. The source lines are connected in parallel and connects second source/drain terminals of the select transistors of the memory cell to a second node.

In another embodiment, a memory cell comprises a one-time programmable (OTP) element and a plurality of select transistors. The OTP element has a first OTP element terminal connected to one or more of bit lines. Each select transistor has a gate terminal connected to a word line, a first source/drain terminal connected to a second OTP element terminal of the OTP element, and a second source/drain terminal connected to one or more source lines, wherein the bit lines are connected in parallel or the source lines are connected in parallel.

In another embodiment, a method of manufacturing a memory device comprises: fabricating a memory cell over a substrate; forming two or more bit lines connected in parallel between a first node and a first one-time programmable (OTP) element terminal of an OTP element of the memory cell by depositing a conductive material in a first metal layer over the memory cell; depositing a conductive material in at least one of a second metal layer below the first metal layer and a third metal layer above the first metal layer to form a word line connected to gate terminals of the select transistors; and depositing a conductive material to form at least one source line. The at least one source line connects second source/drain terminals of the select transistors to a second node.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device comprising:
a plurality of memory cells, each including an one-time programmable (OTP) element and a plurality of select transistors;
a word line connected to gate terminals of the select transistors of a memory cell of the plurality of memory cells;
a plurality of bit lines connected in parallel between a first node and a first OTP element terminal of the OTP element of the memory cell; and
a plurality of source lines connected in parallel and connecting second source/drain terminals of the select transistors of the memory cell to a second node.

2. The memory device of claim 1, wherein the parallel connection of the bit lines reduces total wire resistance to facilitate programming of the OTP element.

3. The memory device of claim 1, wherein:
the bit lines are arranged along a first direction and each extend in a second direction transverse to the first direction; and
the word line extends in the first direction, the memory device further comprising:
an interconnect line substantially parallel to the word line; and
a plurality of vias connecting two or more bit lines to the interconnect line.

4. The memory device of claim 3, wherein the two or more bit lines are adjacent to each other.

5. The memory device of claim 3, wherein a distance between the vias is greater than a distance between the adjacent bit lines.

6. The memory device of claim 1, wherein:
the OTP element includes an anti-fuse that is initially in a non-conductive state and that is configured to become permanently conductive when a programming voltage is applied across the memory cell through the bit lines and the source lines; and
the anti-fuse is formed of a material configured to break down when a programming voltage is applied across the memory cell through the bit lines and the sources form a conductive path.

7. The memory device of claim 1, wherein the select transistors are configured to provide access to the memory cell during programming and reading operations when a high or low select signal is applied to the word line.

8. The memory device of claim 1, further comprising a sense amplifier connected to the bit line and configured to detect a state of the OTP element during a read operation.

9. The memory device of claim 1, wherein the plurality of memory cells include first and second memory cells, the memory device further comprising:
a second word line connected to gate terminals of the select transistors of the first and second memory cells;
a plurality of second bit lines connected in parallel, wherein the OTP element of the first memory cell and the OTP element of the second memory cell are connected between the second bit lines and first source/drain terminals of the select transistors of the first and second memory cells; and
a plurality of second source lines connected in parallel and coupling second source/drain terminals of the select transistors of the first and second memory cells to the ground node.

10. A memory cell comprising:
a one-time programmable (OTP) element having a first OTP element terminal connected to one or more of bit lines; and
a plurality of select transistors, each having a gate terminal connected to a word line, a first source/drain terminal connected to a second OTP element terminal of the OTP element, and a second source/drain terminal connected to one or more source lines, wherein the bit lines or source lines are connected in parallel.

11. The memory cell of claim 10, further comprising one or more dummy OTP elements, each having a first OTP element terminal connected to the one or more bit lines and a second, floating second OTP element terminal.

12. The memory cell of claim 10, further comprising:
a first interconnect line interconnecting the bit lines;
a second interconnect line interconnecting the source lines; and
a third interconnect line interconnecting the first source/drain terminals of the select transistors.

13. The memory cell of claim 12, wherein:
the bit lines are formed in the same metal layer;
the word line is formed in one or more metal layers; and
the first interconnect line is formed in the same metal layer as the word line.

14. The memory cell of claim 12, wherein:
the source lines are formed in the same metal layer;
the word line is formed in one or more metal layers; and
the second interconnect line is formed in the same metal layer as the word line.

15. The memory cell of claim 10, further comprising at least one dummy OTP element having a first OTP element terminal connected to the one or more bit lines and a second, floating second OTP element terminal.

16. A method of manufacturing a memory device, the method comprising:
fabricating a memory cell over a substrate, the memory cell including:
a one-time programmable (OTP) element; and
one or more select transistors; and
depositing a conductive material to form a plurality of metal layers stacked one above the other, wherein the plurality of metal layers include:
a first metal layer including at least one source line that connects the select transistors to a first node;
a second metal layer including a word line connected to gate terminals of the select transistors; and
a third metal layer including a plurality of bit lines connected in parallel between a second node and the OTP element.

17. The method of claim 16, further comprising:
connecting the bit lines in parallel by:
depositing a conductive material in the same metal layer as the word line to form an interconnect line; and
forming a plurality of vias, each of which connects a respective one of the bit lines to the interconnect line.

18. The method of claim 16, further comprising:
connecting the source lines in parallel by:
depositing a conductive material to form an interconnect line; and
forming a plurality of vias, each of which connects a respective one of the source lines to the interconnect line.

19. The method of claim 16, further comprising forming one or more dummy OTP elements each having a first OTP element terminal connected to the bit lines and a second, floating OTP element terminal.

20. The method of claim 16, wherein the memory cell constitute a plurality of memory cells, each connected to the word line and between the two or more bit lines and the at least one source lines.
